(19) United States
(12) Patent Application Publication
(10) Pub. No.: US 2008/0093660 A1
(43) Pub. Date: Apr. 24, 2008

(54) Flash memory device and method for manufacturing the same

(75) Inventors: Hee-Sook Park, Seoul (KR); Byung-Hak Lee, Suwon-si (KR); Tae-Ho Cha, Seongnam-si (KR); Woong-Hee Sohn, Seoul (KR); Jang-Hee Lee, Yongin-si (KR); Jae-Hwa Park, Yongin-si (KR)

Correspondence Address: F.Chau & Associates, LLC, 130 Woodbury Road, Woodbury, NY, 11797, US

(73) Assignee: SAMSUNG ELECTRONICS CO., LTD.

(21) Appl. No.: 11/653,166

(22) Filed: Jan. 12, 2007

(30) Foreign Application Priority Data
Oct. 20, 2006 (KR) 2006-102587

(51) Int. Cl. H01L 29/792; H01L 21/336

(52) U.S. Cl. 257/324; 438/287; 438/591; 438/595; 257/411; 257/412

(57) ABSTRACT

A flash memory device includes a semiconductor substrate, a gate insulating layer having a first width formed on the semiconductor substrate to trap carriers tunneled from the semiconductor substrate and a metal electrode on the gate insulating layer to receive a voltage required for tunneling. The metal electrode having a second width smaller than the first width. The flash memory device further includes a sidewall spacer surrounding a side surface of the metal electrode to prevent oxidation of the metal electrode.

### CROSS-REFERENCE TO RELATED APPLICATIONS

This U.S. non-provisional patent application claims priority under 35 U.S.C. § 119 of Korean Patent Application No. 2006-102587, filed on Oct. 20, 2006, the entire contents of which are hereby incorporated by reference in their entirety.

### BACKGROUND OF THE INVENTION

1. Technical Field

The present disclosure relates to a semiconductor and to a method for manufacturing the same, and more particularly, to a flash memory device capable of preventing oxidation of a metal gate and to a method for manufacturing the same.

2. Description of the Related Art

The semiconductor memory devices which are used for operating microprocessors are typically volatile. In volatile memory devices, when a power supply is stopped, stored data may be erased. Thus, nonvolatile memory devices have been manufactured in an attempt to solve the above-mentioned difficulty of volatile memory devices. For example, flash memory devices have been utilized as one of these nonvolatile memory devices. The flash memory device stores information typically by tunneling carriers to store them in a conductor or trap them in a nonconductor.

In the flash memory device to trap carriers in the nonconductor, an oxide-nitride-oxide (ONO) layer is usually formed on a semiconductor substrate, and a gate electrode is formed of polysilicon. In addition, gates formed of a metal have also been used instead of polysilicon to realize a high operating speed for the flash memory device. However, a difficulty with a gate formed of a metal is that it may be oxidized. For example, when the metal gate is oxidized, the critical dimension (CD) may be deviated from a designed dimension. Consequently, as a result of the above-mentioned oxidation of the gate, it may become difficult to estimate a stable electrical characteristic, and the oxidized metal gate may also serve as a leakage current source. To prevent the oxidation of a metal gate, a method for forming an oxide layer on a sidewall of a metal gate has been utilized. However, although an oxide layer is formed on a sidewall of a gate, the forming of an oxide layer may still lead to oxidation of a metal gate.

### SUMMARY OF THE INVENTION

Embodiments of the present invention provide a flash memory device capable of preventing oxidation of a metal gate and a method for manufacturing the same.

Embodiments of the present invention also provide a flash memory device capable of preventing oxidation of a metal gate during gate patterning by employing a low temperature oxide layer as a sidewall spacer.

In accordance with an embodiment of the present invention, a flash memory device is provided. The flash memory device includes a semiconductor substrate, a gate insulating layer having a first width formed on the semiconductor substrate to trap carriers tunneled from the semiconductor substrate and a metal electrode on the gate insulating layer to receive a voltage required for tunneling. The metal electrode having a second width smaller than the first width. The flash memory device further includes a sidewall spacer surrounding a side surface of the metal electrode to prevent oxidation of the metal electrode.

In some embodiments, the gate insulating layer includes a silicon oxide (SiOₓ) layer, a silicon nitride (SiN) layer, and an aluminum oxide (AlOₓ) layer that are stacked on the semiconductor substrate.

In other embodiments, the metal electrode includes a tantalum nitride (TaN) layer formed on the gate insulating layer and a tungsten layer formed on the TaN layer.

In still other embodiments, the sidewall spacer includes a low temperature oxide layer formed at a temperature which can oxidize the metal electrode. The sidewall spacer further includes a nitride layer. The low temperature oxide layer is formed using a chemical vapor deposition (CVD) or atomic layer deposition (ALD). The low temperature oxide layer includes a vertical section formed on the side surface of the metal electrode and a horizontal section extending from the vertical section and being formed on an upper surface of the gate insulating layer. The low temperature oxide layer has an “L” shape. The low temperature oxide layer is formed at a temperature no greater than about 450° C.

In other embodiments, the low temperature layer includes a material selected from the group consisting of silicon oxide (SiOₓ), aluminum oxide (AlOₓ), hafnium oxide (HfOₓ), zirconium oxide (ZrOₓ), ruthenium oxide (RuOₓ), platinum oxide (PtOₓ), tantalum oxide (TaOₓ) and a combination thereof.

In accordance with an exemplary embodiment of the present invention, a method for manufacturing a flash memory device is provided. The method includes preparing a semiconductor substrate, forming a first insulating layer on the semiconductor substrate, forming a metal electrode layer on the first insulating layer, patterning the metal electrode layer to form a metal electrode having a first width and forming a second insulating layer on a sidewall and an upper surface of the metal electrode and an upper surface of the first insulating layer. The method further includes patterning the second insulating layer to form a sidewall spacer surrounding the sidewall of the metal electrode; and patterning the first insulating layer to form a gate insulating layer having a second width greater than the first width.

In yet other embodiments, the forming of the first insulating layer on the semiconductor substrate includes forming a SiOₓ layer on the semiconductor substrate, forming a SiN layer on the SiOₓ layer and forming an AlOₓ layer on the SiN layer.

In further embodiments, the forming of the metal electrode on the first insulating layer includes: forming a first electrode including TaN on the first insulating layer; and forming a second electrode including tungsten on the first electrode.

In still further embodiments, the forming of the second insulating layer on a sidewall and an upper surface of the metal electrode and an upper surface of the first insulating layer includes: forming an oxide layer on the first insulating layer; and forming a nitride layer on the oxide layer.

In other embodiments, the oxide layer includes a low temperature oxide layer for preventing oxidation of the metal electrode. The low temperature oxide layer is formed using CVD or ALD. The low temperature oxide layer is formed at a temperature no greater than about 450° C.

In yet further embodiments, the low temperature oxide layer includes one material selected from the group consisting of SiOₓ, AlOₓ, HfOₓ, ZrOₓ, RuOₓ, PtOₓ, TaOₓ and combination thereof.

In other embodiments, the patterning of the second insulating layer to form a sidewall spacer surrounding the sidewall of the metal electrode includes patterning the oxide layer to form a sidewall oxide layer in the shape of an “L” including a vertical section formed on a sidewall of the metal electrode and a horizontal section extending from the vertical section and being formed on the first insulating layer.

### BRIEF DESCRIPTION OF THE DRAWINGS

Embodiments of the present invention can be understood in more detail from the following description taken in conjunction with the accompanying drawing in which:

FIG. 1A is a sectional view of a flash memory device according to an embodiment of the present invention;

FIG. 1B is a sectional view of a flash memory device according to a modified embodiment of the present invention;

FIGS. 2A through 2F are sectional views illustrating a method for manufacturing a flash memory device according to an embodiment of the present invention; and

FIGS. 3A and 3B are sectional views illustrating a method for manufacturing a flash memory device according to a modified embodiment of the present invention.

### DETAILED DESCRIPTION OF PREFERRED EMBODIMENTS

Hereinafter, a flash memory device and a method for manufacturing the same will be described in detail with reference to the accompanying drawings.

The present invention may, however, be embodied in different forms and should not be constructed as limited to the embodiments set forth herein.

(An Embodiment of a Flash Memory Device)

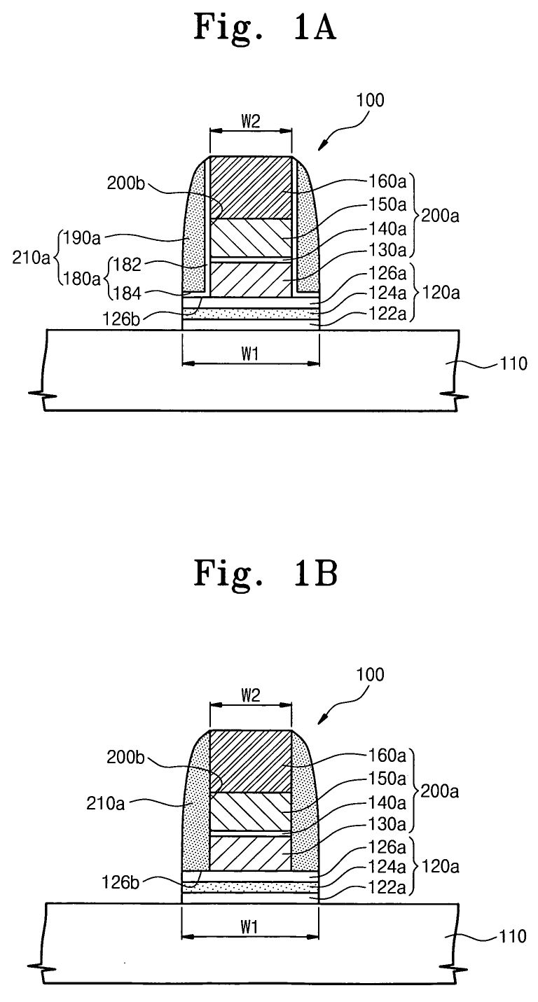

FIG. 1A is a sectional view of a flash memory device according to an embodiment of the present invention.

Referring to FIG. 1A, in the flash memory device, which is one of nonvolatile memory devices storing information by trapping carriers, a metal gate 100 including a gate insulating layer 120a and a metal electrode 200a that are sequentially stacked is disposed on a semiconductor substrate 110 such as, for example, a silicon wafer. The gate insulating layer 120a stores information using the tunneling of carriers and the metal electrode 200a serves as a word line. When a voltage is applied to the metal electrode 200a, carriers are tunneled from the semiconductor substrate 110 to the gate insulating layer 120a and then trapped in the gate insulating layer 120a to store information, while the carriers trapped in the gate insulating layer 120a are tunneled to the semiconductor substrate 110 to erase information.

The gate insulating layer 120a includes a tunnel oxide layer 122a providing a passage where carriers are tunneled, a nitride layer 124a providing a space where carriers are trapped, and a blocking oxide layer 126a preventing the carriers trapped in the nitride layer 124a from moving to the metal electrode 200a. For example, the tunnel oxide layer 122a may be formed of silicon oxide (SiOₓ), the nitride layer 124a may be formed of silicon nitride (SiN), and the blocking oxide layer 126a may be formed of aluminum oxide (AlOₓ).

The metal electrode 200a includes a first electrode 130a formed on the blocking oxide layer 126a and a second electrode 150a formed on the first electrode 130a. The metal electrode 200a may further include a hard mask 160a. The hard mask 160a serves as a mask during gate etch for gate patterning, and may be formed of, for example, nitride or oxide. The first electrode 130a may be formed of a material having a high work function, for example, tantalum nitride (TaN), such that the carriers trapped in the nitride layer 124a cannot move to the metal electrode 200a. When the first electrode 130a is formed of a material having a high work function, a specific resistance thereof increases, which may in turn have a negative effect on the operation speed of the flash memory device. Therefore, the second electrode 150a, which serves as an actual electrode, may be formed of a material having a low specific resistance such as, for example, tungsten (W) to improve the operation speed of the flash memory device.

FIG. 1A illustrates a cell region of the flash memory device. A gate formed in a peripheral region is formed of, for example, polysilicon and a metal such as tungsten. However, direct contact between polysilicon and a metal may lead to an undesirable decrease in electrical characteristics. Therefore, a barrier may be formed between polysilicon and a metal so as to suppress a reaction therebetween. A barrier may be formed in the gate of the cell region. That is, a barrier 140a may be further formed between the first and second electrodes 130a and 150a.

The gate insulating layer 120a may have a width W1 greater than a width W2 of the metal electrode 200a. Accordingly, a leakage current through the gate insulating layer 120a is reduced to improve the electrical characteristic.

When the metal electrode 200a is oxidized while a process is performed, it serves as a leakage current source, thereby decreasing the electrical characteristic. Also, oxidation of the metal electrode 200a causes a bridge between the metal electrodes in a peripheral region. Furthermore, the oxidation of the metal electrode 200a changes the critical dimension (CD) of the metal gate 100 to thereby decrease the electrical characteristics. Therefore, a sidewall spacer 210a may be disposed on a sidewall 200b of the metal electrode 200a to prevent oxidation of the metal electrode 200a. The sidewall spacer 210a prevents the metal electrode 200a from serving as a leakage current source and maintains the critical dimension (CD) of the metal gate 100 constant by preventing oxidation of the metal electrode 200a.

The sidewall spacer 210a, for example, may be formed of a double layer including a sidewall oxide layer 180a and a sidewall nitride layer 190a. The sidewall oxide layer 180a includes a vertical section 182 formed on the sidewall 200b of the metal electrode 200a and a horizontal section 184 extending from the vertical section 182. The horizontal section 184 may be formed on the gate insulating layer 120a, more specifically, on an upper surface 126b of the blocking oxide layer 126a. That is, the sidewall oxide layer 180a may have an “L” shape.

The sidewall oxide layer 180a may be formed at a low temperature to prevent oxidation of the metal electrode 200a, more specifically, oxidation of the second electrode 150a formed of a metal such as tungsten. For example, a low temperature oxide layer that is formed at a temperature no greater than about 450° C. is employed as the sidewall oxide layer 180a. For instance, the sidewall oxide layer 180a may employ a low temperature oxide layer formed in a temperature range of about 400 to about 450° C., or about 200° C. or lower. The sidewall oxide layer 180a may be formed of, for example, silicon oxide (SiOₓ), aluminum oxide (AlOₓ), hafnium oxide (HfOₓ), zirconium oxide (ZrOₓ), ruthenium oxide (RuOₓ), platinum oxide (PtOₓ), tantalum oxide (TaOₓ) or a combination thereof. The sidewall oxide layer 180a may be formed, for example, using chemical vapor deposition (CVD) or by using atomic layer deposition (ALD) such that it is conformally formed on both the sidewall 200b of the metal electrode 200a and the upper surface 126b of the blocking oxide layer 126a.

The sidewall nitride layer 190a may be included in the sidewall spacer 210a to increase the etch selectivity between the blocking oxide layer 126a and the sidewall spacer 210a during spacer etch to be described later. For example, the sidewall nitride layer 190a may be formed of SiN. In a fabrication process, because the sidewall oxide layer 190a prevents oxidation of the metal electrode 200a, the sidewall nitride layer 190a may be formed at a high temperature, for example, a temperature high enough to oxidize tungsten.

In the metal gate 100 of a flash memory device having a so-called TANOS structure where a TaN layer 130a, an oxide layer 126a, a nitride layer 124a, an oxide layer 122a, and a silicon substrate 110 are stacked, the sidewall 200b of the metal electrode 200a is protected by the sidewall oxide layer 180a. Therefore, oxidation of the metal electrode 200a, e.g., particularly, oxidation of the second electrode 150a formed of tungsten is prevented during an etching process for gate patterning. Also, as the sidewall spacer 200a is formed, the width W1 of the gate insulating layer 120a is greater than the width W2 of the metal electrode 200a, thereby decreasing a leakage current through the gate insulating layer 120a.

(A Modified Embodiment of a Flash Memory Device)

FIG. 1B is a sectional view of a flash memory device according to a modified embodiment of the present invention.

Referring to FIG. 1B, a metal gate 100 may include a relatively thick sidewall oxide layer 210a as a sidewall spacer. The sidewall oxide layer 210a may be a low temperature oxide layer that is formed at, for example, a temperature of no greater than about 450° C. For instance, the side wall oxide layer 210a may be a low temperature oxide layer that is formed in a temperature range of about 400 to about 450° C., or about 200° C. or lower, so as to prevent oxidation of a metal electrode 200a, e.g., particularly, oxidation of a second electrode 150a formed of tungsten. For example, the sidewall oxide layer 210a may be formed of SiOₓ, AlOₓ, HfOₓ, ZrOₓ, RuOₓ, PtOₓ, TaOₓ or combination thereof using CVD or ALD. As the modified embodiment of FIG. 1B the same as the previous embodiment of FIG. 1A except for the above-described features, a detailed description of those same features between these embodiments will be omitted herein.

(An Embodiment of a Method for Manufacturing a Flash Memory Device).

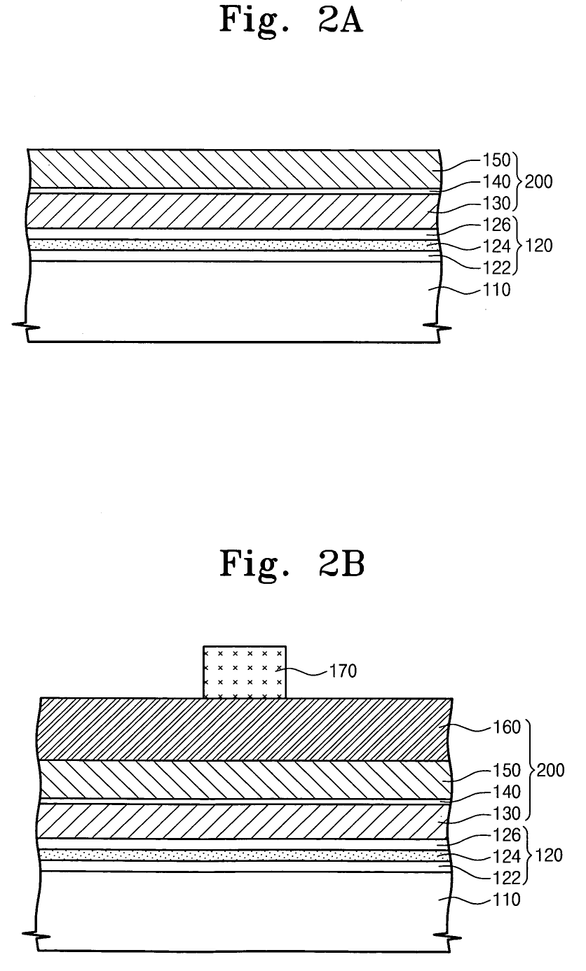

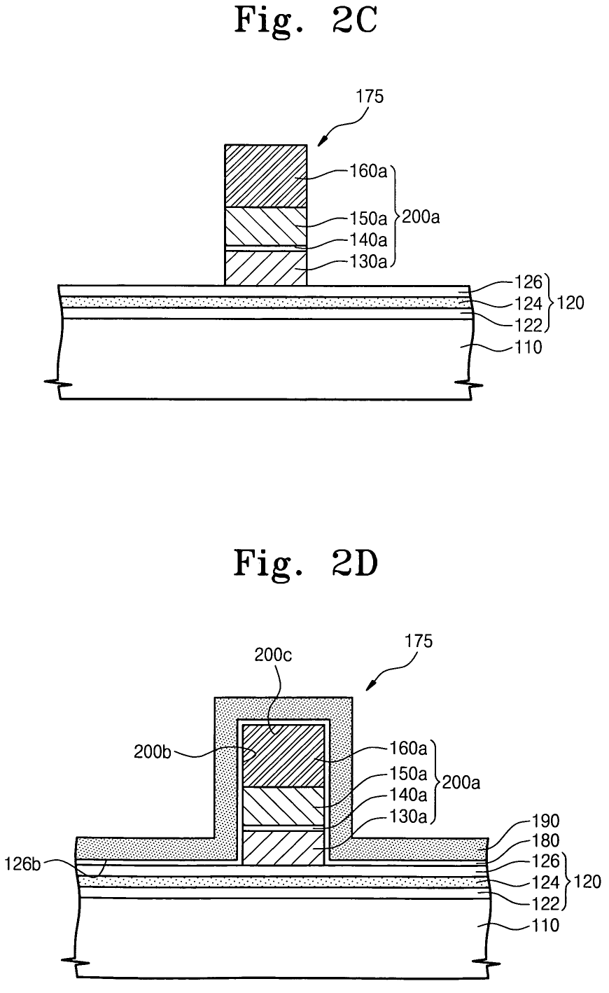

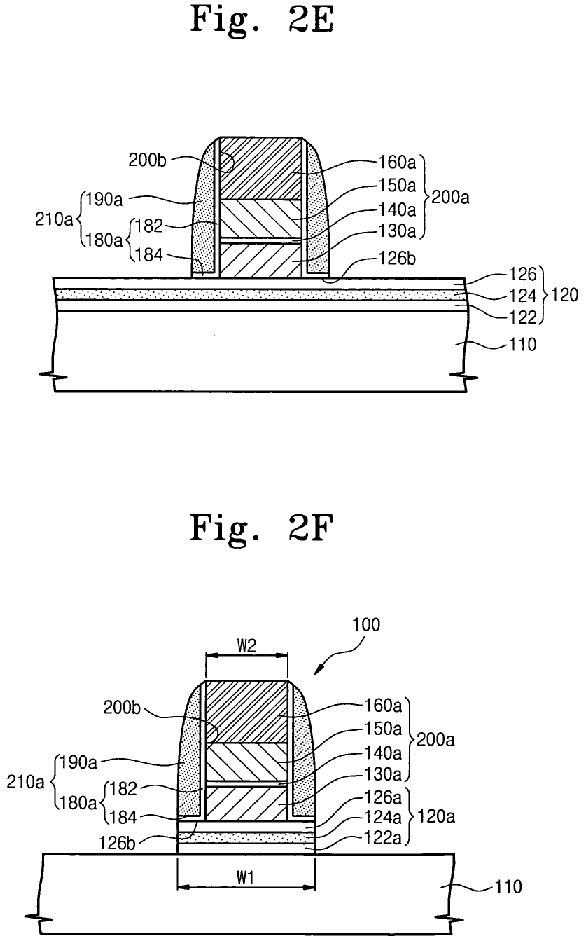

FIGS. 2A through 2F are sectional views illustrating a method for manufacturing a flash memory device according to an embodiment of the present invention.

Referring to FIG. 2A, an insulating layer 120 is formed on a semiconductor substrate 110. The insulating layer 120 is formed by sequentially depositing a first oxide layer 122 as a tunnel oxide layer, a first nitride layer 124 as a carrier trap layer, and a second oxide layer 126 as a blocking oxide layer on the semiconductor substrate 110. The insulating layer 120 is a nonconductor for trapping carriers that are tunneled from the semiconductor substrate 110. For example, the first oxide layer 122 may be formed of SiOₓ, the first nitride layer 124, which is a space where the tunneled carriers are trapped, may be formed of SiN, and the second oxide layer 126, which prevents the carriers trapped in the first nitride layer 124 from migrating, may be formed of AlOₓ.

A metal electrode layer 200 is formed on the insulating layer 120. The metal electrode layer 200 is formed by depositing a first electrode layer 130 on the second oxide layer 126 and depositing a second electrode layer 150 on the first electrode layer 130. For example, the first electrode layer 130 may be formed of TaN having a high work function, and the second electrode layer 150, which serves as an actual electrode, may be formed of tungsten (W) having a low specific resistance. The first electrode layer 130 is formed of TaN having a high work function to prevent the carriers trapped in the first nitride layer 124 from moving to the metal electrode layer 200. As TaN generally has a high specific resistance, it is preferable that the second electrode layer 150 is formed of tungsten having a low specific resistance so as to improve the operation speed of the flash memory device.

A barrier layer 140 may be further formed between the first and second electrode layers 130 and 150. The barrier layer 140 is interposed between polysilicon and a metal included in a gate that is formed in a peripheral region, not in the cell region of the semiconductor substrate 110 illustrated in FIG. 2A, to suppress a reaction between polysilicon and a metal. The barrier layer 140 may be formed in the cell region when is formed in the peripheral region.

Referring to FIG. 2B, a photoresist pattern 170 is formed on the second electrode layer 150 to perform a gate etch process for gate patterning. When the second electrode layer 150 is formed of tungsten, the photoresist pattern 170 may not successfully function during a gate etch process. Therefore, a hard mask layer 160, which serves as a mask during a gate etch process, may be further formed on the second electrode layer 150, in addition to the photoresist pattern 170. That is, the metal electrode layer 200 may further include the hard mask layer 160. The hard mask layer 160 may be formed by depositing nitride or oxide. The hard mask layer 160, the second electrode layer 150, the barrier layer 140, and the first electrode layer 130 are selectively removed through the gate etch process. In the gate etch process, the photoresist pattern 170 is used as a mask, and an etch selectivity between the first electrode layer 130 and the second oxide layer 126 is used. Next, the photoresist pattern 170 is removed. The resulting structure of the gate etch process is illustrated in FIG. 2C.

Referring to FIG. 2C, a gate pattern 175 is formed on the insulating layer 120 through the gate etch process. The gate pattern 175 includes a first electrode 130a, a barrier 140a, a second electrode 150a, and a hard mask 160a that are sequentially stacked. The hard mask 160a may be removed or left remaining. The first electrode 130a, the barrier 140a, the second electrode 150a, and the hard mask 160a constitute a metal electrode 200a.

Referring to FIG. 2D, a third oxide layer 180 is formed on the semiconductor substrate 110. That is, the third oxide layer 180 is formed on a sidewall 200b and an upper surface 200c of the metal electrode 200a, and an upper surface 126b of the second oxide layer 126. The third oxide layer 180 prevents oxidation of the metal electrode 200a, e.g., particularly, oxidation of the second electrode 150a formed of tungsten. Therefore, the third oxide layer 180 may be formed at a low temperature oxide layer formed at a relatively low temperature where oxidation of tungsten does not occur. For example, the third oxide layer 180 is conformally formed at a temperature of no greater than about 450° C. For example, the third oxide layer 180 may be formed at a temperature from about 400 to about 450° C., or about 200° C. or lower using CVD or ALD. The third oxide layer 180 may be formed by, for example, depositing SiOₓ, AlOₓ, HfOₓ, ZrOₓ, RuOₓ, PtOₓ, TaOₓ or a combination thereof.

For example, a SiO₂ layer may be formed as the third oxide layer 180 through a chemical reaction represented as following formula 1 at a temperature of about 105° C.

Si₂H₆+H₂O+pyridine→SiO₂·xH₂O+C₅H₅N:H—Cl [Formula 1]

Next, a second nitride layer 190 may be further formed on the third oxide layer 180 to obtain an etch selectivity with respect to the second oxide layer 126 during a spacer etch process to be performed later. As the third oxide layer 180 is already formed, the nitride layer 190 may be formed without limitations in the forming of the third oxide layer 180. That is, the second nitride layer 190 may be formed under higher temperature conditions than that used for the metal electrode 200a, e.g., the second electrode 150a formed of tungsten, which as discussed is susceptible to oxidation. The second nitride layer 190 may be formed of SiN. Next, the third oxide layer 180 and the second nitride layer 190 are selectively removed to form a sidewall spacer 210a through the spacer etch process.

Referring to FIG. 2E, the sidewall spacer 210a includes a patterned third oxide layer 180a and a patterned second nitride layer 190a to prevent oxidation of the second electrode 150a. The patterned third oxide layer 180a may include a vertical section 182 formed on the sidewall 200b of the metal electrode 200a and a horizontal section 184 formed on the upper surface 126b of the second oxide layer 126, and have an “L” shape. The spacer etch process is successively performed to selectively remove the second oxide layer 126, the first nitride layer 124, and the first oxide layer 122.

Referring to FIG. 2F, a gate insulating layer 120a including a patterned second oxide layer 126a, a patterned first nitride layer 124a, and a patterned first oxide layer 122a is formed on the semiconductor substrate 110 through the successive spacer etch process. Consequently, a metal gate 100 is formed. As the sidewall spacer 210a includes the second nitride layer 190a, the sidewall spacer 210a and the patterned second oxide layer 126a, one may sufficiently obtain an etch selectivity during the spacer etch process. The sidewall spacer 210a formed on the sidewall 200b of the metal electrode 200a prevents oxidation of the metal electrode 200a, and also serves as a mask during the spacer etch process. Therefore, the gate insulating layer 120a is formed to have a width W1 greater than a width W2 of the metal electrode 200a.

Selectively, a heat treatment may be performed to recover etch damage after the spacer etch process. Here, the etch damage may include etch damage of the gate pattern 175 (refer to FIG. 2C) caused by the gate etch process. The heat treatment may be performed for example, at a temperature from about 800 to about 900° C. For example, the heat treatment may be performed at about 850° C. for approximately 30 minutes. As the etch damage is recovered using the heat treatment, a leakage current can be reduced, which may be generated in a side surface of the metal gate 100.

(A Modified Embodiment of a Method for Manufacturing a Flash Memory Device)

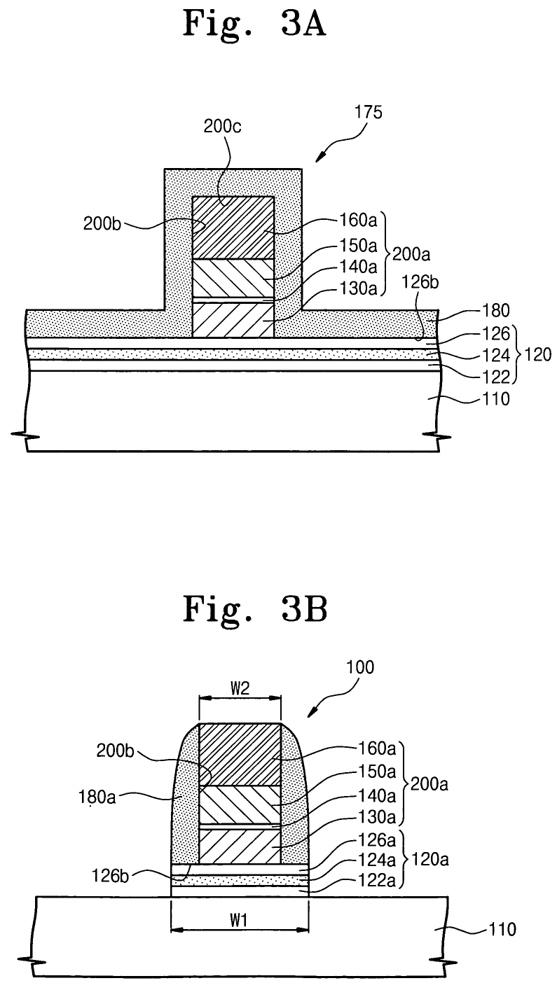

FIGS. 3A and 3B are sectional views illustrating a method for manufacturing a flash memory device according to a modified embodiment of the present invention.

Referring to FIG. 3A, as described with reference to FIGS. 2A through 2C, an insulating layer 120 including a first oxide layer 122, a first nitride layer 124, and a second oxide layer 126 that are sequentially stacked, and a metal electrode 200a including a first electrode 130a, a barrier 140a, a second electrode 150a, and a hard mask 160a that are sequentially stacked are formed on a semiconductor substrate 110. The barrier 140a may be not formed, and the hard mask 160a may be removed.

When the metal electrode 200a is formed through a gate etch process, a third oxide layer 180 is formed on the semiconductor substrate 110. That is, the third oxide layer 180 is formed on a sidewall 200b and an upper surface 200c of the metal electrode 200a and an upper surface 126b of the second oxide layer 126. The third oxide layer 180 may be formed by depositing, for example, SiOₓ, AlOₓ, HfOₓ, ZrOₓ, RuOₓ, PtOₓ, TaOₓ or a combination thereof at a relatively low temperature to prevent oxidation of the metal electrode 200a, e.g., the second electrode 150a formed of tungsten. The third oxide layer 180 may be conformally formed using, for example, CVD or ALD. The third oxide layer 180 is selectively removed through a spacer etch process.

Referring to FIG. 3B, a third oxide layer 180a patterned through the spacer etch process is disposed on the sidewall 200b of the metal electrode 200a to serve as a sidewall spacer. Also, a gate insulating layer 120a having a width W1 greater than a width W2 of the metal electrode 200a is formed through the spacer etch process.

As described above, according to embodiments of the present invention, a sidewall of a metal gate of a flash memory device can be protected by a low temperature oxide layer, thereby preventing oxidation of the sidewall. Accordingly, a leakage current is reduced, thereby improving the electrical characteristic of the flash memory device.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A flash memory device, comprising:
a semiconductor substrate;
a gate insulating layer having a first width on the semiconductor substrate to trap carriers tunneled from the semiconductor substrate;
a metal electrode on the gate insulating layer to receive a voltage required for tunneling, the metal electrode having a second width smaller than the first width; and
a sidewall spacer surrounding a side surface of the metal electrode to prevent oxidation of the metal electrode.

2. The flash memory device of claim 1, wherein the gate insulating layer comprises a silicon oxide (SiOₓ) layer, a silicon nitride (SiN) layer, and an aluminum oxide (AlOₓ) layer that are stacked on the semiconductor substrate.

3. The flash memory device of claim 1, wherein the metal electrode comprises a tantalum nitride (TaN) layer on the gate insulating layer and a tungsten layer on the TaN layer.

4. The flash memory device of claim 1, wherein the sidewall spacer comprises a low temperature oxide layer formed at a temperature which can oxidize the metal electrode.

5. The flash memory device of claim 4, wherein the sidewall spacer further comprises a nitride layer formed on the low temperature oxide layer.

6. The flash memory device of claim 4, wherein the low temperature oxide layer is formed using one of chemical vapor deposition (CVD) and atomic layer deposition (ALD).

7. The flash memory device of claim 4, wherein the low temperature oxide layer is formed at a temperature no greater than about 450° C.

8. The flash memory device of claim 4, wherein the low temperature oxide layer comprises:
a vertical section formed on the side surface of the metal electrode: and
a horizontal section extending from the vertical section and being formed on an upper surface of the gate insulating layer,
wherein the low temperature oxide layer has an “L” shape.

9. The flash memory device of claim 4, wherein the low temperature layer comprises one selected from the group consisting of silicon oxide (SiOₓ), aluminum oxide (AlOₓ), hafnium oxide (HfOₓ), zirconium oxide (ZrOₓ), ruthenium oxide (RuOₓ), platinum oxide (PtOₓ), tantalum oxide (TaOₓ) and combination thereof.

10. A method for manufacturing a flash memory device, the method comprising:
providing a semiconductor substrate;
forming a first insulating layer on the semiconductor substrate;
forming a metal electrode layer on the first insulating layer;
patterning the metal electrode layer to form a metal electrode having a first width;
forming a second insulating layer on a sidewall and an upper surface of the metal electrode and an upper surface of the first insulating layer;
patterning the second insulating layer to form a sidewall spacer surrounding the sidewall of the metal electrode; and
patterning the first insulating layer to form a gate insulating layer having a second width greater than the first width.

11. The method of claim 10, wherein the forming of the first insulating layer on the semiconductor substrate comprises:
forming a silicon oxide SiOₓ layer on the semiconductor substrate;
forming a silicon nitride (SiN) layer on the SiOₓ layer; and
forming an aluminum oxide AlOₓ layer on the SiN layer.

12. The method of claim 10, wherein the forming of the metal electrode on the first insulating layer comprises:
forming a first electrode including tantalum nitride (TaN) on the first insulating layer; and
forming a second electrode including tungsten on the first electrode.

13. The method of claim 10, wherein the forming of the second insulating layer comprises:
forming an oxide layer on the first insulating layer; and
forming a nitride layer on the oxide layer.

14. The method of claim 13, wherein the oxide layer includes a low temperature oxide layer for preventing oxidation of the metal electrode.

15. The method of claim 14, wherein the low temperature oxide layer is formed using one of chemical vapor deposition (CVD) and atomic layer deposition (ALD).

16. The method of claim 14, wherein the low temperature oxide layer is formed at a temperature no greater than about 450° C.

17. The method of claim 14, wherein the low temperature oxide layer includes a material selected from the group consisting of silicon oxide (SiOₓ), aluminum oxide (AlOₓ), hafnium oxide (HfOₓ), zirconium oxide (ZrOₓ), ruthenium oxide (RuOₓ), platinum oxide (PtOₓ), tantalum oxide (TaOₓ) and combination thereof.

18. The method of claim 13, wherein the forming of the sidewall spacer comprises patterning the oxide layer to form a sidewall oxide layer in the shape of an “L” including a vertical section formed on a sidewall of the metal electrode and a horizontal section formed on the first insulating layer extending from the vertical section.
